(19) United States
(12) Patent Application Publication
(10) Pub. No.: US 2006/0179395 A1
(43) Pub. Date: Aug. 10, 2006

(54) Method and circuit arrangement for verifying a data record having a plurality of data words

(75) Inventor: Steffen Marc Sonnekalb, Taufkirchen (DE)

Correspondence Address: DICKSTEIN SHAPIRO MORIN & OSHINSKY LLP., 1177 AVENUE OF THE AMERICAS 6TH AVENUE, NEW YORK, NY, 10036-1400, US

(73) Assignee: Infineon Technologies AG, Munich (DE)

(21) Appl. No.: 11/333,552

(22) Filed: Jan. 16, 2006

(30) Foreign Application Priority Data
Jan. 14, 2005 (DE) 10 2005 001 953.6

(51) Int. Cl. H03M 13/00

(52) U.S. Cl. 714/758

(57) ABSTRACT

A method for verifying a data record having a plurality of data words, the method including the steps of providing an encrypted data record having a plurality of encrypted data words and an error codeword assigned to the data record. After the decryption of the encrypted data words, it is verified whether the error codeword is to be assigned to the decrypted data words. If the error codeword is not to be assigned, an alarm action is performed.

### CROSS-REFERENCE TO RELATED APPLICATION

This application claims priority to German Patent Application Serial No. 10 2005 001 953.6, which was filed on Jan. 14, 2005, and is incorporated herein by reference in its entirety.

### FIELD OF THE INVENTION

The invention relates to a method and a circuit arrangement for verifying a data record having a plurality of data words as claimed in the independent claims.

### BACKGROUND OF THE INVENTION

In security-relevant circuit arrangements, data is normally protected by using a cryptographic unit. The cryptographic unit decrypts the data before it is actually used, for example for processing in a central processing unit, and encrypts the data so that it only exists in encrypted form, for example, when saved in a memory, so as to make unauthorized reading of the data or systematic data manipulation more difficult. The cryptographic unit is usually arranged between the central processing unit and the memory.

Errors can occur in the memory itself or in the process of data transfer from the memory to the cryptographic unit. The errors are either random bits changes or systematic manipulations of the memory or a communication path, also known as a data bus, to the cryptographic unit. With random bits changes or manipulations occurring over a short period, often only a few bits, sometimes just a single bit, are involved. Error correction codes (ECC) are used to guarantee the accuracy of the data, even in these situations, in particular for the single errors as they are known, and to prevent any impact on their processing.

The error correction codes are applied to the pre-encrypted data, so that the encryption comprises two mutually independent encryption steps. In addition to the actual cryptographic unit for decryption and encryption, a dedicated piece of extra hardware is required for this, which is used to perform the steps of the relatively complex error correction coding plus correction.

The additional current consumption associated with the extra hardware is a disadvantage, in particular in portable applications, for example in chip cards.

### SUMMARY OF THE INVENTION

It is the object of the present invention to describe a method for data verification and correction using the functions provided by the cryptographic unit.

The object is achieved by a method for verifying a data record having a plurality of data words including the steps of providing an encrypted data record having encrypted data words, providing an error codeword assigned to the encrypted data record, decryption of the encrypted data words of the encrypted data record, verifying whether the error codeword is to be assigned to the decrypted data words of the decrypted data record, and performing an alarm action if the error codeword is not assigned to the decrypted data words of the decrypted data record.

In addition, this object is achieved by a circuit arrangement for verifying data words, which is based on the method according to the invention.

### BRIEF DESCRIPTION OF THE DRAWINGS

The invention is described below by means of exemplary embodiments with reference to the drawings, in which:

FIG. 1 shows a structure of a data word;

FIG. 2 shows a circuit arrangement containing a cryptographic unit, which is connected directly to the input of a memory;

FIG. 3 shows an alternative circuit arrangement containing the cryptographic unit, which is connected directly to the input of a central processing unit;

FIG. 4 shows an exemplary embodiment of a cryptographic unit to which are input a data record and an error codeword;

FIG. 5 shows an alternative exemplary embodiment of a cryptographic unit to which are input various data records and an error codeword;

FIG. 6 shows the procedure of an encryption of a data record by the cryptographic unit;

FIG. 7 shows the procedure of a decryption and a correction of an encrypted data record by the cryptographic unit;

FIG. 8 shows a table containing an example data record and an assigned error codeword;

FIG. 9 shows a table containing an encrypted data record and an encrypted error codeword with reference to FIG. 8;

FIG. 10 shows a table containing a decrypted data record, a decrypted error codeword and an error syndrome with reference to FIG. 9;

FIG. 11 shows a table containing a corrected data record with reference to FIG. 10; and

FIG. 12 shows a table containing an encrypted, corrected data record with reference to FIG. 11, and differences from the encrypted data record with reference to FIG. 9.

### DETAILED DESCRIPTION OF PREFERRED EMBODIMENTS OF THE INVENTION

A circuit arrangement and method for verifying a data record having a plurality of data words including the steps of providing an encrypted data record having encrypted data words, providing an error codeword assigned to the encrypted data record, decryption of the encrypted data words of the encrypted data record, verifying whether the error codeword is to be assigned to the decrypted data words of the decrypted data record, and performing an alarm action if the error codeword is not assigned to the decrypted data words of the decrypted data record.

The data transfer up to and including the decryption of the data record in the cryptographic unit is protected by the method according to the invention.

The encrypted data words are generated by an encryption of the data words to be protected.

The error codeword is generated using a code-generated, preferably linear superposition, or any function, of input words of an input data record, whose output data word is the error codeword. The data record, to which an error codeword is assigned, is used as the input data record. Hence the information from all the data words of the data record is combined in the error codeword. The error codeword is also advantageously first encrypted before it is input to the cryptographic unit, and then decrypted.

An advantageous alarm action comprises the correction of the decrypted data words, so that bit errors do not impact on the data processing. The decrypted data words of the decrypted data record and the error codeword are provided for correcting the encrypted data words. An error syndrome, which indicates whether, or to what extent, the error codeword can be assigned to the decrypted data record, is generated from the decrypted data words and the error codeword. The data words are corrected, if necessary, by correcting their bits corresponding to the deviations from the error codeword indicated by the error syndrome. By this means, the erroneous data word that led to error indicators in the error syndrome is also corrected.

For quick correction it is sensible for each data word to be computed from the other data words and the error codeword.

The code-generated, linear superposition that is used to generate the error codeword is advantageously an exclusive-OR operation on the data words of the data record, which is not complex to implement. In this operation, an i-th bit of all data words of the data record are combined to generate an i-th bit of the error codeword. Alternatively, the exclusive-OR operation on the data sequence can also be performed on a different permutation of each of the data words to make it more difficult to draw an inference from the error codeword about the exclusive-ORed data words combined within it.

When using one of the code-generated, linear superpositions described above, the data word can be corrected by an exclusive-OR operation between the data-word bit assigned to the i-th bit of the error codeword and the i-th bit of the error syndrome. This exclusive-OR operation is simple to implement as well.

The additional steps of the method are based on the assumption that the errors are located in one word, or that it is a single-bit error. The corrected data words are re-encrypted and compared with the encrypted data words provided, so that deviations produced by the correction are identified. The difference between each encrypted data word and the associated encrypted, corrected data word is found for the whole data record, and the data word having the smallest difference is selected.

Assuming that the fewest possible bit errors occurred only in a single encrypted data word, then the data word having the smallest difference between the corresponding encrypted data word and the corresponding encrypted, corrected data word is selected and corrected. In particular if one assumes single errors, the comparison is made easier by searching merely for a deviation of one bit. The search for the minimum difference is thereby simplified. The correction is not performed for the other data words of the data record because the underlying assumption is that just one word is erroneous.

The difference between two data words is defined as the number of bits that differ between them.

The circuit arrangement according to the invention for verifying a data record having a plurality of data words comprises a cryptographic unit, which on its part comprises an input for the input of a data record having encrypted data words and of an error codeword, a decryption device, which is designed to decrypt the encrypted data words of the encrypted data record, a logic device, which is designed to combine the decrypted data words and the error codeword into an error syndrome, and a comparison device, which is designed to compare the error syndrome with a preset value.

Apart from the decryption device, the embodiment of the cryptographic unit comprises only a few additional simple hardware elements for enabling implementation of the method, which can be integrated easily in a conventional cryptographic unit.

The cryptographic unit is advantageously designed to decrypt an encrypted error codeword. The error codeword hence also exists at the cryptographic unit in encrypted form, making it more difficult to infer the encryption used and/or the encrypted data.

In addition, the cryptographic unit is designed to correct the decrypted data words if the decrypted data words are not to be assigned to the error codeword. This feature means that it is not only possible to identify data errors in the data words but also to correct them.

Furthermore, the cryptographic unit is designed to encrypt the corrected data words so that the decryption and the encryption are provided by one unit.

In addition, the cryptographic unit is designed to compare each of the encrypted data words of the encrypted data record with a corresponding encrypted, corrected data word of an encrypted, corrected data record, and to find a difference in order to enable an evaluation of the correction. Assuming that the fewest possible errors occurred only in a single encrypted data word, the data word having the smallest difference is selected as the erroneous word. A particularly simple embodiment is based on the assumption of a single-bit error, so that the evaluation of the difference is limited to whether the deviation equals one bit. When a data record of decrypted data words is output by the cryptographic unit, the selected data word is output in corrected form; the other data words of the data record are merely decrypted without correction.

The cryptographic unit is used in circuit arrangements and arranged between a central processing unit and a memory in order to guarantee secure data transfer between these two units. Normally the cryptographic unit is connected directly to the input of the memory and can also be integrated in it.

The encryption of the data words by the cryptographic unit can be designed by providing an additional input for supplying an item of address information and encrypting the data words depending on the address information. This provides an additional safeguard, which also includes the assignment of data information to an item of address information. Erroneous address retrievals are detected as errors and suggest a possible manipulation. This embodiment lends itself to the arrangement of the cryptographic unit directly beside the central processing unit that provides the address information.

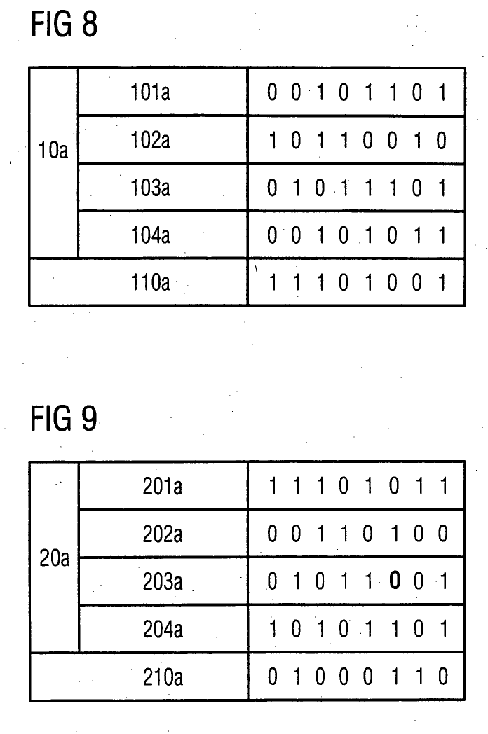

FIG. 1 shows a structure of a data word comprising n bits. A typical data word comprises 32 bits for example. It should be mentioned here that the example data words in tables of FIGS. 8 to 12 each comprise eight bits to make the method clearer and easier to understand.

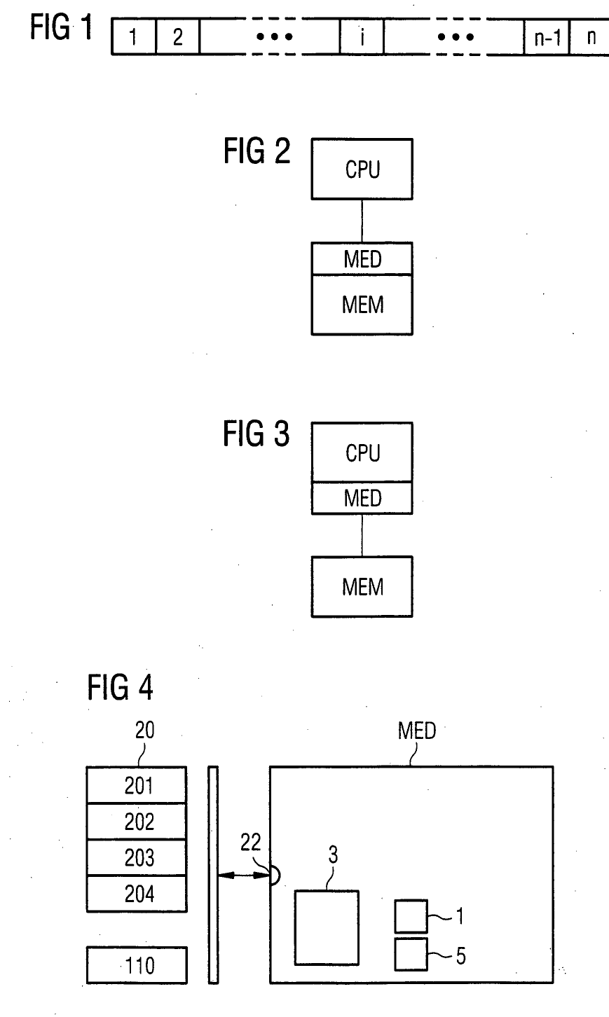

FIG. 2 shows a circuit arrangement comprising a central processing unit CPU and a memory MEM. A cryptographic unit MED is arranged between the central processing unit CPU and the memory MEM. In the exemplary embodiment shown, the cryptographic unit MED is connected directly to the input of the memory MEM. This embodiment is advantageous regarding integration of the two units.

FIG. 3 shows an alternative embodiment of the circuit arrangement in which the cryptographic unit MED is arranged directly in front of the central processing unit CPU. Data is not only protected in the memory MEM by this means, but the data is also protected up to the transfer into the central processing unit CPU, i.e. also on the bus paths there. The data is not provided in unencrypted form until just before its actual use in the central processing unit CPU. This increases the immunity of the circuit arrangement to data changes and manipulations.

The circuit arrangement can have both a modular and an integrated design, for example for use in a chip card.

FIG. 4 shows a simple exemplary embodiment of a cryptographic unit MED according to the invention, to which is input an encrypted data record 20 and an error codeword 110. The encrypted data record 20 comprises a plurality of encrypted data words 201, 202, 203, 204. The number of data words has been selected to be four in this example. Obviously a different number, for example eight, is conceivable. The encrypted data record 20 and an error codeword 110 is input to an input 22 of the cryptographic unit MED. The cryptographic unit MED can also be designed with additional inputs such that the error codeword 110 is input to one of these inputs, and the encrypted data words 201, 202, 203, 204 of the encrypted data record 20 to the others. The form of input is irrelevant; it can be both parallel and serial.

The error codeword 110 can be input to the cryptographic unit MED both in unencrypted form and in encrypted form. In principle, the form of input does not impact on the error detection and error correction. Nevertheless, it is advantageous if the error codeword 110 is also input to the cryptographic unit in encrypted form. The encryption means that all the data at the input to the cryptographic unit, for example from the memory MEM, exists in encrypted form which hampers their unauthorized decryption in an attack.

The error codeword 110 is assigned to the encrypted data words 201, 202, 203, 204 of the encrypted data record 20, and is generated from these prior to their encryption by means of a code-generated logical operation. When the encrypted data record 20 is saved, the error codeword 110 is also saved. Even though in this case additional memory space is required compared with the actual data, it should be mentioned that additional memory space is also required with error correction coding, when redundant information is added to the data word in order to correct any errors that arise.

The cryptographic unit MED according to the invention shown in FIG. 4 is suitable for comparing an encrypted data record 20 with an associated error codeword 110. In the cryptographic unit MED, a decryption device 3 is provided for decrypting the encrypted data record 20. If the error codeword exists in encrypted form, the decryption device 3 is also used for decrypting this. The decrypted data words 301, 302, 303, 304 that exist internally and the error codeword 110 are combined by a logic device 1 into a new error syndrome 320. The error syndrome 320 is compared in a comparison device 5 with a preset value, in order to establish whether the error codeword 110 can be assigned to the decrypted data words 301, 302, 303, 304, so that one can assume an error-free data record.

The cryptographic unit MED described is a simple embodiment, which can be used only to display errors in the applied encrypted data record 20. Such an embodiment is suitable only for indicating incident errors, for instance by an alarm signal to be output. It is advantageously operated in parallel with an actual cryptographic unit used only for decryption and encryption.

FIG. 5 shows an advantageous development of a cryptographic unit MED. This embodiment enables both the encryption of a data record 10 and the decryption of an encrypted data record 20, and, if necessary, the correction of an erroneous, encrypted data word 201, 202, 203, 204. The embodiment has both an encryption device 2, by means of which the data words 101, 102, 103, 104 of the data record 10 are encrypted, and a decryption device 3 for decrypting an encrypted data record 20 and, if necessary, an encrypted error codeword 210.

In addition to the functions already described for FIG. 4, it is also possible using the embodiment shown in FIG. 5 to assign an error codeword to the data words 101, 102, 103, 104 of the data record 10 input via an input 11 by using the logic device 1. This is output together with the encrypted data words 201, 202, 203, 204 either in unencrypted form or advantageously in encrypted form via an input/output 22. Obviously, a separate input and a separate output can also be provided instead of the input/output 22.

In the decryption, the encrypted data record 20 and the encrypted error codeword 210 are input via an input/output 22.

If, after the decryption of the encrypted data record 20 and the verification using the error codeword 110, it is established that the error codeword 110 is not to be assigned to the data record, a correction of the decrypted data record 30 that exists internally is possible. The correction uses the encryption device 2 and a device 4 for finding the difference. The decrypted data words 301, 302, 304 are output together with the corrected data word 403 via an output 33. If an error is found in the error codeword, the decrypted data words are output without correction.

It should be pointed out here that the exemplary embodiments shown in FIGS. 4 and 5 can be combined.

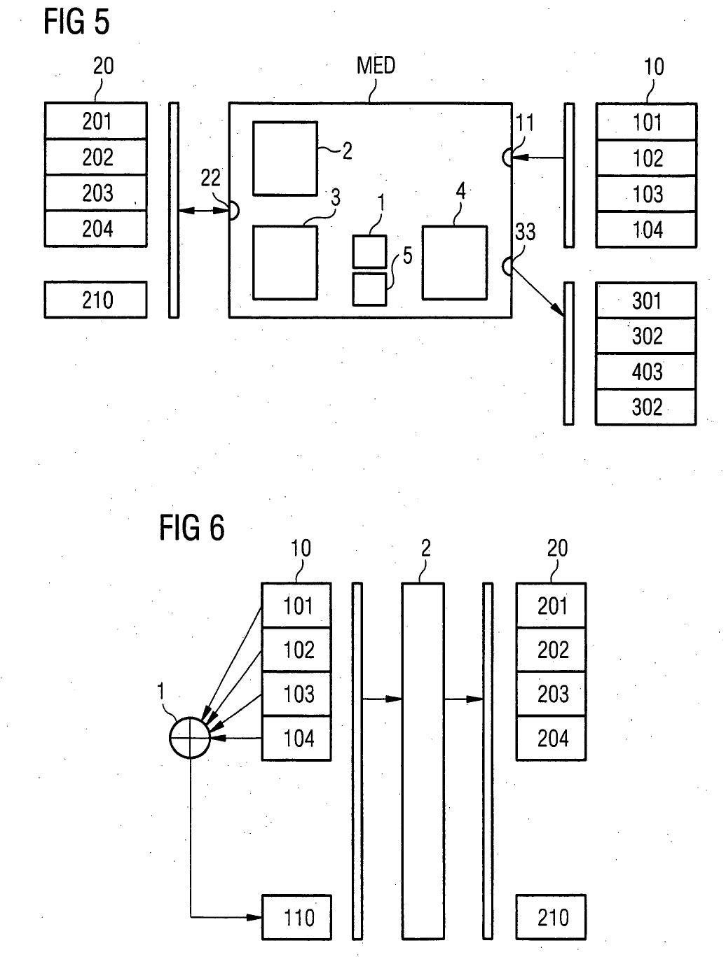

FIG. 6 shows the procedure of an encryption to generate the encrypted data record 20 together with the associated error codeword 110. Generally this method step is also implemented by the cryptographic unit, which both encrypts and decrypts.

A data record 10, in this case composed of four data words 101, 102, 103, 104 by way of example, is combined to generate an error codeword 110. The error codeword 110 contains the same number of bits as each of the data words 101, 102, 103, 104. A logic element 1 implementing a code-generated, linear logical operation is used for the combining operation. In this case, the data words 101, 102, 103, 104 of the data record 10 are combined by an exclusive-OR operation. The exclusive-OR operation is performed in the following simple way: the first bits of the data words 101, 102, 103, 104 are combined by an exclusive-OR operation into the first bit of the error codeword 110. Similarly, the second bits of the data words 101, 102, 103, 104 are combined by the exclusive-OR operation into the second bit of the error codeword 110. The same applies to the i-th bit of the data words, which are combined into the i-th bit of the error codeword.

In an alternative combination, a permutation of the bits of each data word is performed prior to the exclusive-OR operation. The following combination is possible: the first bit of a first data word 101, the second bit of a second data word 102, the third bit of a third data word 103 and the fourth bit of a fourth data word 104 are combined by an exclusive-OR operation into the first bit of the error codeword 110. The second bit of the error codeword 110 is generated by a combination of the second bit of the first data word 101, the third bit of the second data word 102, the fourth bit of the third data word 103 and the fifth bit of the fourth data word 104. The remaining bits of the error codeword 110 are generated analogously. Obviously, other permutations are also possible or just the permutation of some of the data words 101, 102, 103, 104. In these combinations, one bit from each of the data words 101, 102, 103, 104 is assigned to the i-th bit of the error codeword 110. Conversely, precisely one bit of the error codeword 110 is also assigned to each bit of one of the data words 101, 102, 103, 104.

The data words 101, 102, 103, 104 of the data record 10 and the error codeword 110 are encrypted by means of an encryption device 2, so that a first encrypted data word 201 is to be assigned to a first data word 101. This also applies to the other data words 102, 103, 104 of the data record 10. The error codeword 110 is also advantageously converted into an encrypted error codeword 210 by the encryption device 2. This procedure has the advantage that when the encrypted data record 20 is saved, the error codeword 110 is also saved in encrypted form to make unauthorized decryption by an attacker more difficult.

The encryption selected is usually a highly non-linear transformation, which makes unauthorized decryption more difficult. “Highly non-linear” means that a small difference between two data words, for instance, that differ by one bit, after the encryption results in completely differently encrypted data words that differ from each other by significantly more bits. Equally, it may be the case that two data words exhibiting a large difference are converted into similar encrypted data words that differ by just one or two bits for example. Obviously, the encryption and the associated decryption involve a unique transformation.

The encryption, error detection and correction by the method according to the invention is illustrated by tables in FIGS. 8 to 12 by means of an example data record 10a. The example data record 10a comprises four example data words 10a, 102a, 103a, 104a, each having eight bits. FIGS. 8 and 9, which illustrate the encryption, are considered first.

FIG. 8 shows how the i-th bit of the error codeword 110a is generated by the exclusive-OR operation on the i-th bit of each of the example data words 101a, 102a, 103a, 104a of the example data record 10a.

FIG. 9 shows the corresponding encrypted data words 201a, 202a, 203a, 204a and the encrypted, assigned error codeword 210a. The encryption used is irrelevant to the method, although it is important to realize that it is highly non-linear. A single error, which may arise by a manipulation after the encryption for example, is highlighted in bold in the third encrypted data word 203a.

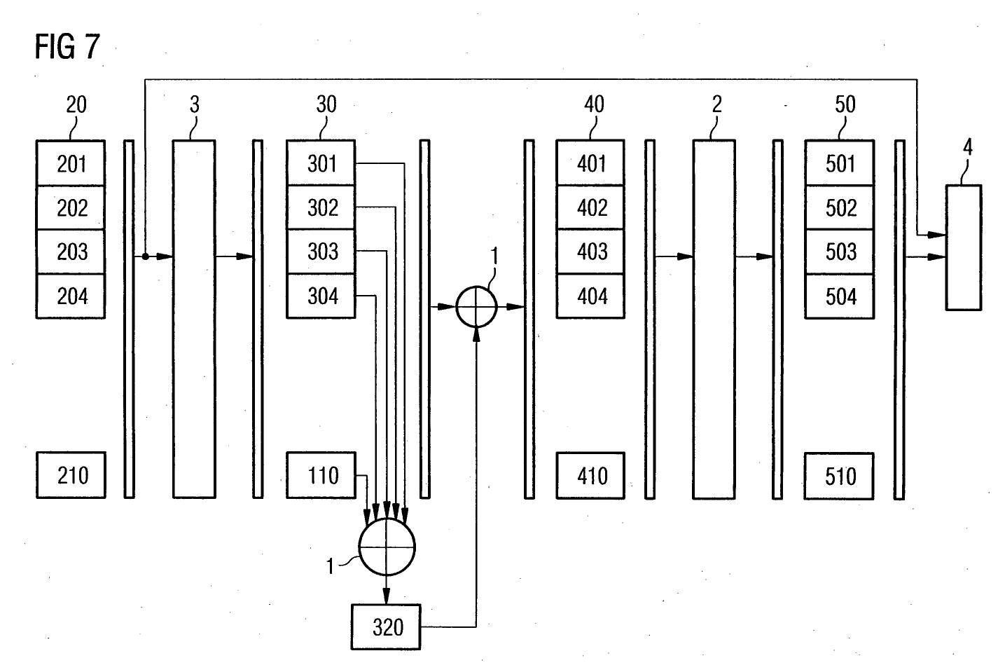

FIG. 7 shows the method steps for decrypting the encrypted data words 201, 202, 203, 204 and their verification and, if necessary, correction. The encrypted data words 201, 202, 203, 204 of the encrypted data record 20 are converted by a decryption device 3 into the decrypted data record 30, which comprises the decrypted data words 301, 302, 303, 304. If the error codeword 110 is also present in encrypted form, it is also decrypted as shown in FIG. 7.

The encryption device 2 and the decryption device 3 is a decryption-encryption device pair, so that if the two devices are connected in series and applied consecutively to a data record, the data record is output unchanged.

The decrypted data words 301, 302, 303, 304 of the decrypted data record 30 are compared with the error codeword 110 by generating an error syndrome 320. The comparison is made by the decrypted data words 301, 302, 303, 304 being combined with each other in the same way as for generating the error codeword 110, and comparing the resultant word with the error codeword 110. The error syndrome 320 is obtained by an exclusive-OR operation between the resultant word and the error codeword 110.

This comparison is achieved simply and without the intermediate step of the re-generation of the resultant word if, in addition to the i-th bit of the data words 301, 302, 303, 304 being input to an exclusive-OR operation 1, which is also used for generating an i-th bit of the error codeword, the i-th bit of the error codeword 110 is also input. This means that the combination of the decrypted data words 301, 302, 303, 304 and the comparison of the resultant word with the error codeword 110 can be performed in one step by the exclusive-OR operation 1. If the error codeword 110 can be assigned to the decrypted data words 301, 302, 303, 304 of the decrypted data record 30, then the generated error syndrome 320 is a zero vector that contains only “0” bits. If an i-th bit of the error codeword does not equal the correspondingly assigned combination of the bits of the decrypted data words 301, 302, 303, 304, then the i-th bit of the error syndrome is a “1”, which indicates an error. With the exclusive-OR operation, the i-th bit that is “1” indicates an error in the i-th position of a data word. Obviously it is also possible for more than one bit of the error syndrome 320 not to equal “0”. Given the assumption that a single error has occurred within the encrypted data record 20, and the decryption is highly non-linear, this situation is to be presumed.

If the error syndrome 320 does not equal the zero vector, the following error correction procedure is applied. The bits of each decrypted data word 301, 302, 303, 304 of the decrypted data record 30, which are assigned to the error positions corresponding to those indicated in the error syndrome 320, are corrected, so that a corrected data record 40 exists. If only one data word of the decrypted data record 30 was erroneous, then after the correction all the other data words except for the formerly incorrect one contain errors. Even if the error codeword 110 is no longer needed for the subsequent procedure for correcting the erroneous data word, the following procedure can also be applied to the error codeword in the same way. This action has the advantage that the error to be found obviously may not occur just in the encrypted data words 201, 202, 203, 204, but also in the error codeword 110. If this situation is detected, there is also no need to correct the decrypted data words 301, 302, 303, 304.

FIG. 10 shows the example encrypted data record 20a from FIG. 9 after decryption. The first data word 301a, the second data word 302a and the fourth data word 304a after decryption match the original first, second and fourth data word 10a, 102a, 104a respectively. The individual bit error of the encrypted third data word 203a results in five bit errors (highlighted in bold) after decryption, owing to the strong non-linearity of the encryption and decryption operation. The error syndrome 320a is formed by an exclusive-OR operation between the decrypted first data word 301a, the second decrypted data word 302a, the decrypted third data word 303a, the decrypted fourth data word 304a and the decrypted error codeword 101a. It does not equal “0” at those bit positions that are erroneous in the third decrypted data word 303a. This indicates the position of the bit errors in one of the data words 301a, 302a, 303a, 304a, but not in which one.

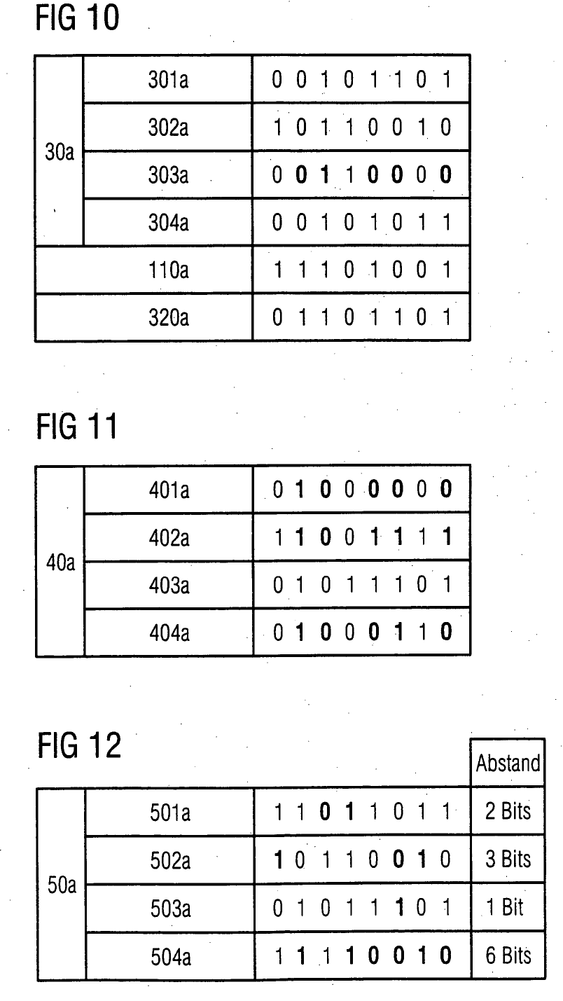

FIG. 11 shows the corrected data words 401a, 402a, 403a, 404a. After the correction of the corresponding positions in each of the decrypted data words 301a, 302a, 303a, 304a of the decrypted data record 30a, the third corrected data word 403a now exists in corrected form and matches the original third data word 103a. The other corrected data words 401a, 402a, 404a are erroneous at the corresponding positions.

For the sake of clarity, the subsequent tables in FIGS. 11 and 12 do not include a correction of the error codeword 110.

FIG. 7 shows the subsequent procedure for detecting the erroneous word. The now corrected data words 401, 402, 403, 404 are re-encrypted by the encryption device 2. The same can be performed on the corrected error codeword 410. The encrypted, corrected data words 501, 502, 503, 504 are now compared with the originally encrypted data words 201, 202, 203, 204. This is advantageously performed by a device 4 for determining the distance. The distance is defined as the number of bits by which two data words differ.

The difference between the example encrypted, corrected data record 50a and the example original, encrypted data record 20a can be seen in FIGS. 9 and 12. The erroneously encrypted, third data word 203a and the encrypted, corrected third data word 503a differ only by one bit, although five bits have been corrected in the decrypted third data word 303a. Five bits have also been changed by the correction in the corrected first, second and fourth data word 301a, 302a, 304a. Owing to the strong non-linearity of the encryption, the encrypted, corrected first, second and fourth data word 501a, 502a, 504a differ by more than one bit from the corresponding encrypted data words 210a, 202a, 204a. Assuming that only a single error has occurred, the data word having the smallest difference, in this case the third data word, is assumed to be erroneous, and the correction performed in the previous step is adopted and the corrected third data word 403a is output. The correction is not adopted for the other data words, and the previously determined decrypted data words 301a, 302a, 304a are output.

If one assumes a single error, the selection of the erroneous data word can be further simplified by a suitable embodiment of the comparison device 4. Instead of finding the minimum difference of the data words, it suffices to determine merely whether the difference equals one bit. If this is the case, then this is the data word to be corrected.

Although the example data record from the tables of FIGS. 8 to 12 and the explanation are based mainly on single errors, the above considerations are also possible for multiple bit errors, which must arise only in one of the data words, however. In this case, the data word having the smallest difference is selected, even if two or three errors are involved here.

Since a highly non-linear encryption operation is used, it is also conceivable of course that a difference of just 1 bit occurs between a decrypted data word, of which it is assumed that no error occurred in its decryption, and the corresponding corrected data word after the re-encryption. In this case, the correction cannot work perfectly, because it is not possible to distinguish between the correct word having the 1 bit difference and the erroneous word having the 1 bit difference. In such cases, the algorithm either delivers no result or the correct word is output possibly containing errors.

The probability that a bit error cannot be corrected using this method in this way equals 1:33,000,000 for a data record comprising four 32-bit words. The probability that an erroneous word is not detected or is output containing a bit error equals 1:27,000,000. Hence the reliability of the method described lies in the range of traditional error correction codes.

What is claimed is:

1. A method for verifying a data record having a plurality of data words, comprising the steps of:
providing a first encrypted data record having first encrypted data words;
providing an error codeword assigned to the first encrypted data record;
decrypting the first encrypted data words of the first encrypted data record;
verifying whether the error codeword is to be assigned to the decrypted data words of the decrypted data record; and
performing an alarm action if the error codeword is not assigned to the decrypted data words of the decrypted data record.

2. The method as claimed in claim 1, wherein prior to the step of providing the error codeword, the method further comprising the steps of:
providing an encrypted error codeword; and
decrypting the encrypted error codeword.

3. The method as claimed in claim 1, wherein the first encrypted data words of the first encrypted data record are generated by an encryption from second data words of a second data record.

4. The method as claimed in claim 3, further comprising the step of providing a code-generated superposition of an input data record for generating an output word, the second data record being the input data record, and the error codeword being the output word.

5. The method as claimed in claim 4, wherein the step of performing an alarm action comprises the step of correcting the decrypted data words or correcting the decrypted data words and the error codeword.

6. The method as claimed in claim 5, wherein the step of correcting the decrypted data words or correcting the decrypted data words and the error codeword comprises the steps of:
providing the decrypted data words of the decrypted data record;
providing the error codeword;
generating an error syndrome, which comprises a plurality of bits having a first and a second state, and which indicates by means of the states of the bits whether the error codeword is assigned to the decrypted data words of the decrypted data record, or to what extent the error codeword cannot be assigned to the decrypted data words of the decrypted data record; and
if the error codeword is not assigned to the decrypted data words of the decrypted data record, generating corrected data words from the decrypted data words or generating corrected data words and a corrected error codeword from the decrypted data words and the error codeword, respectively, where a correction is made depending on the error syndrome.

7. The method as claimed in claim 6, wherein the error syndrome is generated by an exclusive-OR operation between the output word of the code-generated superposition using the decrypted data record as input data record, and the error codeword.

8. The method as claimed in claim 6, wherein the step of providing the code-generated superposition comprises the step of generating the i-th bit of the output word by the exclusive-OR operation on one bit of each input word respectively of the input data record, where the bit of each input word is assigned to the i-th bit of the output word.

9. The method as claimed in claim 8, wherein the i-th bit of each input word respectively is assigned to the i-th bit of the output word.

10. The method as claimed in claim 8, wherein the correcting step comprises the step of correcting the bit of each decrypted data word assigned to the i-th bit of the error codeword by the exclusive-OR operation with the i-th bit of the error syndrome.

11. The method as claimed in claim 9, wherein the correcting step comprises the step of correcting the i-th bit of each decrypted data word by the exclusive-OR operation with the i-th bit of the error syndrome.

12. The method as claimed in claim 6, further comprising the step of generating encrypted, corrected data words by the encryption of the corrected data words.

13. The method as claimed in claim 12, further comprising the step of comparing the encrypted, corrected data words of an encrypted, corrected data record with the corresponding first encrypted data words of the first encrypted data record.

14. The method as claimed in claim 13, wherein a corrected data word is determined from a corrected data record having a smallest difference between the corresponding encrypted, corrected data word and the corresponding first encrypted data word, which replaces the corresponding decrypted data word of the decrypted data record.

15. The method as claimed in claim 13, wherein a corrected data word is determined from a corrected data record having a difference of 1 between the corresponding encrypted, corrected data word and the corresponding first encrypted data word, which replaces the corresponding decrypted data word of the decrypted data record.

16. A circuit arrangement for verifying a data record having a plurality of data words, having a cryptographic unit comprising:
an input for the input of an encrypted data record having encrypted data words and of an error codeword;
a decryption device, which is designed to decrypt the encrypted data words of the encrypted data record into decrypted data words of a decrypted data record;
a logic device, which is designed to combine the decrypted data words and the error codeword into an error syndrome; and
a comparison device, which is designed to compare the error syndrome with a preset value.

17. The circuit arrangement as claimed in claim 16, wherein the decryption device is designed to decrypt an encrypted error codeword.

18. The circuit arrangement as claimed in claim 16, wherein the cryptographic unit is designed to correct the decrypted data words of the decrypted data record.

19. The circuit arrangement as claimed in claim 18, wherein the cryptographic unit has an encryption unit, which is designed to encrypt corrected data words into encrypted, corrected data words, or corrected data words and the error codeword into encrypted, corrected data words and an encrypted, corrected error codeword, respectively.

20. The circuit arrangement as claimed in claim 19, wherein the cryptographic unit is designed to compare each of the encrypted data words of the encrypted data record with the corresponding encrypted, corrected data word of an encrypted, corrected data record.

21. The circuit arrangement as claimed in claim 20, wherein the cryptographic unit is designed to output the corrected data word from a corrected data record having a smallest difference between the corresponding encrypted data word and the corresponding encrypted, corrected data word.

22. The circuit arrangement as claimed in claim 20, wherein the cryptographic unit is designed to output the corrected data word from a corrected data record having a difference of one bit between the corresponding encrypted data word and the corresponding encrypted, corrected data word.

23. The circuit arrangement as claimed in claim 16, wherein the cryptographic unit is arranged between a central processing unit and a memory.

24. The circuit arrangement as claimed in claim 16, wherein the cryptographic unit is connected to the input of the memory.

25. The circuit arrangement as claimed in claim 16, wherein the cryptographic unit is designed to encrypt data words.

26. The circuit arrangement as claimed in claim 16, wherein the cryptographic unit has an additional input for supplying an item of address information, and is designed to encrypt data words and/or the corrected data words depending on the address information.

27. The use of a circuit arrangement as claimed in claim 16 in a chip card.

28. A cryptographic unit for verifying a data record having a plurality of data words, comprising:
means for providing a first encrypted data record having first encrypted data words;
means for providing an error codeword assigned to the first encrypted data record;
means for decrypting the first encrypted data words of the first encrypted data record;
means for verifying whether the error codeword is to be assigned to the decrypted data words of the decrypted data record; and
means for performing an alarm action if the error codeword is not assigned to the decrypted data words of the decrypted data record.

29. A circuit arrangement for verifying a data record having a plurality of data words, having a cryptographic unit comprising:
an input means for inputting an encrypted data record having encrypted data words and an error codeword;
a decryption means for decrypting the encrypted data words of the encrypted data record into decrypted data words of a decrypted data record;
a logic means for combining the decrypted data words and the error codeword into an error syndrome; and
a comparison means for comparing the error syndrome with a preset value.
